(19) United States
(12) Patent Application Publication
(10) Pub. No.: US 2010/0162017 A1
(43) Pub. Date: Jun. 24, 2010

(54) SYSTEMS AND METHODS FOR IMPLEMENTING STANDBY FUNCTIONALITY USING FIELD PROGRAMMABLE GATE ARRAYS

(75) Inventors: William John Testin, Indianapolis, IN (US); Yefim Vayl, Carmel, IN (US); John Walter Englert, Carmel, IN (US)

Correspondence Address: FLETCHER YODER P.C., 7915 FM 1960 RD. WEST, SUITE 330, HOUSTON, TX, 77070, US

(73) Assignee: Shenzhen TCL New Technology LTD, Shenzhen (CN)

(21) Appl. No.: 12/600,940

(22) PCT Filed: Jul. 17, 2007
(86) PCT No.: PCT/US07/16216

§ 371 Date: Nov. 19, 2009

(30) Foreign Application Priority Data
Jun. 28, 2007 (CN) CN200710076235.9

(51) Int. Cl. G06F 1/32; H03K 19/0175; H03K 19/177

(52) U.S. Cl. 713/320; 326/62; 326/39

(57) ABSTRACT

The disclosed embodiments relate to an electronic device comprising a logic circuit comprising a plurality of logic banks. In accordance with embodiments of the present technique, at least one of the plurality of banks is configured to provide standby functionality to the electronic device. The electronic device further comprises a power supply coupled to the logic circuit, configured to power the at least one bank without powering all of the plurality of banks.

### CROSS REFERENCE TO RELATED APPLICATION

This application claims priority to Chinese (CN) National Patent Application No. CN 200710076235.9 filed on Jun. 28, 2007, which is incorporated by reference as though completely set forth herein.

### FIELD OF THE INVENTION

The present invention relates to standby control of electronic devices using either a local keyboard or an infra-red (IR) receiver. The proposed invention is intended to be used in electronic devices, such as televisions (TVs), high definition televisions (HDTVs), digital versatile video recorders (DVDRs), video cassette recorders (VCRs), personal digital assistants (PDAs), video cameras, cell phones and so forth.

### BACKGROUND OF THE INVENTION

This section is intended to introduce the reader to various aspects of art which may be related to various aspects of the present invention which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Electronic devices, such as those mentioned above, are typically adapted to maintain some level of functionality even while the device itself may be turned off. Such functionality is needed so that, for example, a user utilizing a local keyboard or a remote control may conveniently access the electronic device from a distance to turn the device on. Accordingly, while the electronic device is off, IR burst/signals transmitted by a remote control are detected by the electronic device and, subsequently, undergo processing by dedicated circuitry and/or software configured to decode the information contained in the IR signals. Thereafter, the decoded information may be forwarded to a main processor of the electronic device so that the commands and/or functions may be executed accordingly.

Executing either a “power on” command from either a local keyboard or an IR remote requires powering components, such as dedicated integrated circuits (ICs) and microprocessors, while the electronic device is off. As mentioned, this requires powering the electronic device's main processor and ICs during relatively long periods of time even though the device is turned off. Consequently, in such instances electronic components within the electronic device may consume large amounts of electrical power of which only a small amount is actually necessary to, for example, implement IR decoding for switching the electronic device on. Further, due to the inherent size of the aforementioned ICs, it is currently not feasible to implement the above mentioned functionalities at low power due to high power leakages of the device's chip sets. As a result, much power is wasted when the electronic device is idle, potentially rendering the electronic device non-compliant with industry standards of power consumption.

### SUMMARY OF THE INVENTION

Certain aspects commensurate in scope with the disclosed embodiments are set forth below. It should be understood that these aspects are presented merely to provide the reader with a brief summary of certain forms the invention might take and that these aspects are not intended to limit the scope of the invention. Indeed, the invention may encompass a variety of aspects that may not be set forth below.

The disclosed embodiments relate to an electronic device comprising a logic circuit comprising a plurality of logic banks. In accordance with the present technique, at least one of the plurality of logic banks is configured to provide standby functionality to the electronic device. The electronic device further comprises a power supply coupled to the logic circuit such that the power supply is configured to power the at least one bank without powering all of the plurality of banks.

### BRIEF DESCRIPTION OF THE DRAWINGS

Advantages of the invention may become apparent upon reading the following detailed description and upon reference to the drawings in which:

FIG. 1 is a schematic diagram of a remotely operated electronic device in accordance with an exemplary embodiment of the present invention;

FIG. 2 is a schematic diagram of another electronic device, in accordance with an exemplary embodiment of the present invention;

FIG. 3 is a block diagram illustrating allocation of voltages and/or currents to components of a control and FPGA module shown in FIG. 2, in accordance with an embodiment of the present invention; and

FIG. 4 is a flow chart of a method of operation of an electronic device in accordance with an exemplary embodiment of the present invention.

### DETAILED DESCRIPTION OF THE PREFERRED EMBODIMENT

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

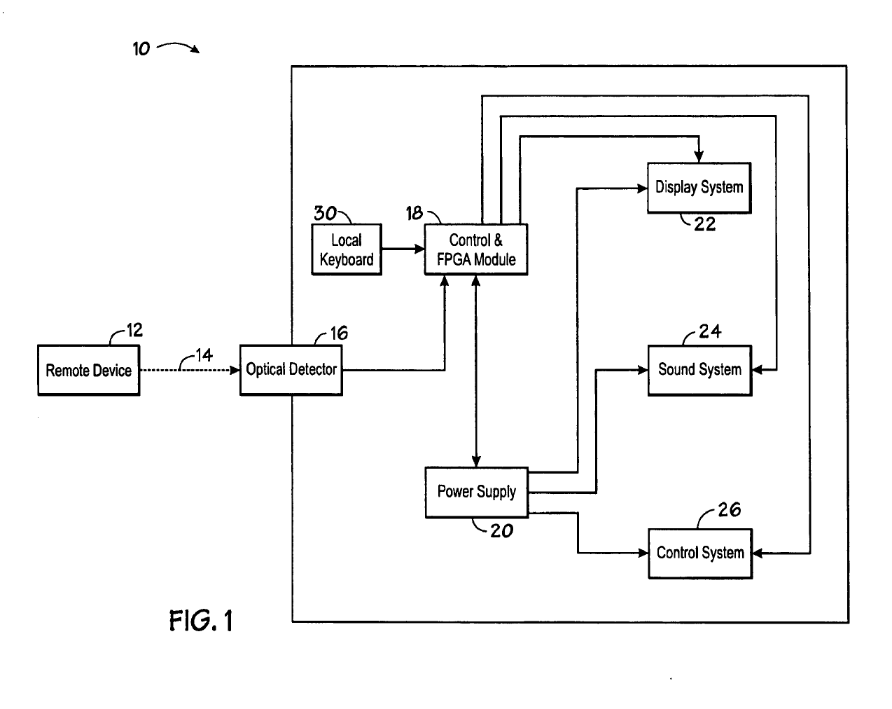

FIG. 1 is a schematic diagram of a keyboard or remotely operated electronic device 10 in accordance with an exemplary embodiment of the present invention. The electronic device 10 may be an HDTV, a computer, a DVDR, a VCR, a PDA, a video camera, a cell phone or the like. The device 10 is controlled by a remote device 12, such as a remote control, configured to transmit IR signals 14 to the electronic device 10. The IR signals 14 emitted by the remote control 12 encode various operational commands and functions enabling, for example, a user to switch the device 10 on and off, change the channels of the device 10 and/or control other settings and features of the device 10, that is, features and configurations normally incorporated in the previously mentioned electronic devices.

As further depicted in FIG. 1, the electronic device 10 is formed of various circuits, devices, software and the like adapted to intercept, process and execute incoming IR signals generated by a local keyboard 30 or emitted by the remote control 12. Accordingly, the electronic device 10 is comprised of an optical detector 16, such as a photodetector, adapted to receive the IR signals 14 and convert such IR signals into electrical signals so that these may be forwarded for processing by additional hardware of the electronic device 10. The electronic device 10 further includes a control and field programmable gate module (FPGA) 18, connected to a local keyboard 30 and the detector 16 and to a power supply 20. The control and FPGA module 18 may be coupled to other systems included in the electronic device 10, including display systems 22, sound systems 24 and control systems 26. Systems 22-26 are also coupled to the power supply 20 providing those systems with operating power.

When the electronic device 10 is fully operational, i.e., turned on (also referred herein as to RUN mode), the control and FPGA module 18 receives and processes signals from the local keyboard or the encoded IR commands that control the systems 22-26. For example, where the electronic device 10 is an HDTV, the control and FPGA module 18 may process certain commands received from the remote control 12 to control the HDTV's brightness and/or sound pitch as provided by the display and sound systems 22 and 24, respectively.

In an exemplary embodiment of the present invention, the control and FPGA module 18 may include processing components, such as a microprocessor, volatile and/or nonvolatile memory elements and field programmable gate arrays (FPGAs) formed of programmable logic blocks and programmable interconnects typically comprising semiconductor devices. The FPGAs may be programmable to emulate the functionality of basic logic gates such as AND, OR, XOR, NOT or more complex combinational functions such as decoders or math functions. The control and FPGA module 18 may also include memory elements, which may be simple flip-flops or complete blocks of memory. In the illustrated embodiment, and as further discussed below the control and FPGA module 18 is adapted to implement IR decoding in a manner that enables the electronic device 10 to consume low amounts of power while it is turned off, or in a low power mode such as a standby (STBY) mode. It should be appreciated that the control and FPGA module 18 may be adapted to perform numerous operations, many of which may be active during periods of time when the electronic device is on (i.e., RUN mode) and, some of which may be unrelated to decoding IR signals.

Accordingly, when the electronic device 10 is in STBY mode, the power supply 20 provides low but sufficient power to those components of the control and FPGA module implementing IR decoding. Accordingly, circuit blocks within the control and FPGA module 18 designated for local keyboard and IR decoding during STBY are adapted to consume low amounts of power such that the overall consumption of power by the electronic device 10, when switched off, is low as well. As a result, such a configuration may render the electronic device 10 compliant with industry standards, one of which is known as “Energy Star,” an industry standard requiring electronic devices employing IR decoders to consume low amounts of power. An additional energy standard with which the electronic device 10 may be compliant is a California energy standard, requiring electronic devices, such as those described herein, to consume less than 3 Watts of power while in STBY mode.

When the device 10 is switched to RUN, the power supply 20 provides additional power to the control and FPGA module 18 to enable its complete operation.

Those of ordinary skill in the art will appreciate that implementing IR decoding during STBY and RUN mode using the control and FPGA module 18 requires no additional hardware and/or software in addition to what is normally included in electronic devices, such as those mentioned above. Thus, to the extent that, for example, existing FPGAs (such as those included in module 18) of the electronic device 10 are configurable for IR decoding, the present technique does not require any additional components to be added to the electronic device 10. In another exemplary embodiment, the FPGA may only contain a subset of the decoding for either the local keyboard or the IR receiver. For example, to switch from standby to run mode, only the “power” button decoding is necessary from either the local keyboard or the remote device. Other buttons like “volume up/down” are not required. In the illustrated embodiment, the main microprocessor may already include a full IR decode component, so that the IR decode circuitry in the FPGA is simplified to include only, for example, “power on” and “power toggle” functions.

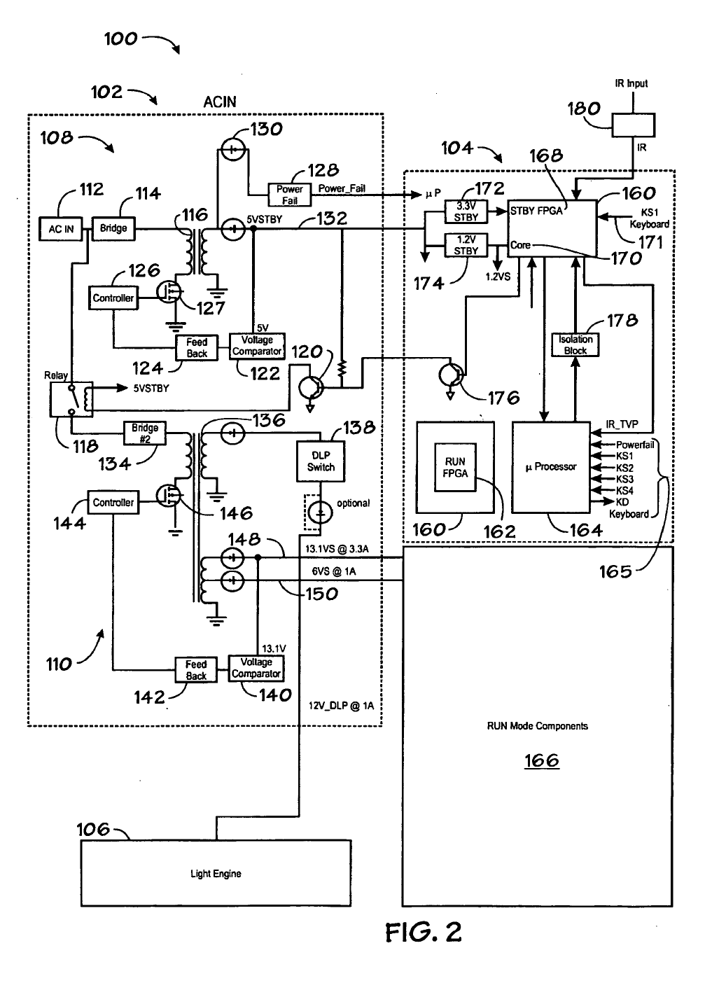

FIG. 2 is a block diagram of an electronic device 100 in accordance with an exemplary embodiment of the present invention. FIG. 2 includes detailed depictions of logic and power components included in electronic devices, such as those mentioned above, implementing lower power consumption while in STBY mode in accordance with present industry standards. The electronic device 100 includes three major modules, namely, a power supply module 102, a control and FPGA module 104, and a light-engine module 106. The power supply module 102 is divided into two sub-modules, referenced as a STBY power supply 108 and a RUN power supply 110. Accordingly, the STBY power supply 108 is adapted to power the electronic device 100 during STBY mode, and the RUN power supply 110 is adapted to power the electronic device 100 during RUN mode.

The STBY power supply 108 includes an AC input 112 configured to receive external AC power. The AC input 112 is coupled to bridge 114, which in turn is coupled to a transformer 116. The bridge 114 is further coupled to a relay switch 118 which is also coupled to transistor 120. The transistor 120 and the switch 118 are configured to connect the control and FPGA module 104 to the power supply 102 module, particularly to RUN power supply 110, as the electronic device 100 transitions from STBY to RUN mode.

Further, the transformer 116 is coupled to a voltage comparator 122, which in turn is coupled to a feedback circuit 124, also known as an opto-isolator. The feedback circuit 124 is coupled to a controller 126 configured to control metal oxide semiconductor field emission transistor (MOSFET) 127. The voltage comparator 122, the feedback circuit 124, the controller 126 and the MOSFET 127 are part of a control and feedback mechanism configured to ensure that standby voltage delivered by the STBY power supply 108 is maintained at a desired level when powering the control and FPGA module 104. While the present embodiment sets the STBY voltage at 5.0 volts, other embodiments may utilize different STBY voltages so as to achieve operating STBY functionality in accordance with the present technique.

Further, the transformer 116 is coupled, via diode 130, to power fail mechanism 128. The power fail mechanism 128 is adapted to trigger warnings in the event the electronic device 100 experiences an abrupt power failure while in STBY mode. Accordingly, the power failure mechanism 128 may further be adapted to enable circuits and/or subsystems configured to ensure certain information, such as time of day (TOD), is not lost and saved in case the electronic device 100 loses power unexpectedly. As further illustrated by FIG. 2, power connection line 132 connects the STBY power supply 108 to the control and FPGA module 104. The connection line 132 is adapted to deliver power to those components of the control and FPGA module 104 operating in STBY mode.

Turning to the RUN power supply 110, FIG. 2 illustrates components of the RUN power supply 110 similar to those described above with respect to the STBY power supply 108. Accordingly, the RUN power supply 110 includes a bridge 134 coupled to the relay switch 118. The bridge 134 is also coupled to a transformer 136, which in turn is coupled to a switch 138. The switch 138 is directly coupled to the light engine 106, such that, when the switch 138 is closed, the transformer 136 becomes connected to the light engine 106 during RUN mode. The transformer 136 is further coupled to a voltage comparator 140 and a feedback circuit 142. The feedback circuit 142 is coupled to a controller 144, which controls MOSFET 146. Similar to the STBY power supply 108, the voltage comparator 140, the feedback circuit 142, the controller 144 and the MOSFET 146 form a control and feedback mechanism adapted to maintain the power and/or voltage delivered by the transformer 136 at a desired level while the electronic device 100 operates in RUN mode.

As further illustrated by FIG. 2, connection lines 148 and 150 connect the RUN power supply 110 to those components of the control and FPGA module 104 that operate in RUN mode. In the illustrated embodiment, voltages provided by the RUN power supply 110 via connection lines 148 and 150 may be set to, for example, 13 and 6 volts, respectively. It should be appreciated that aforementioned operating voltages are exemplary, and that other embodiments in accordance with the present technique may utilize different voltages to power corresponding components of the control and FPGA module 104 in RUN mode.

Turning to the control and FPGA module 104, the module includes FPGA 160 which includes a RUN FPGA 162 and a STBY FPGA 168. While FIG. 2 may show RUN FPGA 162 and STBY FPGA 168 as two separate FPGA components, it should be noted that both of the aforementioned components are part of a single FPGA, namely FPGA 160. Control and FPGA module 104 further includes a controller/microprocessor 164 and RUN mode components 166. The FPGA 160 is adapted to process logic operations whenever the electronic device 100 is in STBY or RUN mode (such as, whenever the electronic device 100 is turned on/off). Accordingly, the RUN FPGA 162 and the controller/microprocessor 164 are adapted to perform most if not all logic operations whenever the electronic device 100 is turned on. As will be appreciated by those of ordinary skilled in the art, the RUN FPGA 162 and the controller/microprocessor 164 may comprise standard hardware and/or software components including memory elements i.e., flash memory, magnetic memory and/or optical memory elements, drivers, video cards, or the like. As further illustrated, controller/microprocessor 164 is provided with keyboard inputs 165 similar to the keyboard inputs 30 described above in relation to FIG. 1. Further, the RUN components 166 include additional circuitry, such as microcontrollers, chipsets, memory elements and so forth, normally used to support the operability of the RUN FPGA 162 and/or of the controller/microprocessor 164.

The FPGA 160 further includes STBY FPGA logic banks 168 and core logic 170. The STBY logic banks 168 and the core logic 170 are both adapted to perform logic operations associated with, for example, IR decoding, as implemented whenever the electronic device 100 may be switched from STBY to RUN mode. Accordingly, the FPGA 160 is provided with a matrix keyboard 171 whose input may be processed by the FPGA 160 to, for example, activate the relay switch 118 when powering the electronic device 100 as it transitions from STBY to RUN mode. Further, the FPGA 160 is coupled to voltage regulators 172 and 174, adapted to power the STBY FPGA logic banks 168 and the core logic 170, respectively. The voltage regulators 172 and 174 are each coupled to the power supply module 102, in particular to STBY power supply 108, which provides desired voltages to the voltage regulators 172 and 174. Further, the FPGA 160 is coupled to transistor 176, which in turn is coupled to transistor 120. Upon activation, the transistor 176 is adapted to close the relay switch 118 so that the control and FPGA module 104 may become fully powered as it transitions from STBY to RUN mode.

Those skilled in the art will appreciate that the microprocessor 164 and the FPGA 160 may be connected through intermediary circuitry (some of which is not illustrated), enabling the microprocessor 164 and the FPGA 160 to work in tandem as the electronic device transitions from STBY to RUN mode or vice versa. Accordingly, one such circuit may include an isolation block 178 adapted to reset or flush/zero-out the FPGA 160 upon its initial configuration and/or initialization during startup of the electronic device 100, while preventing inadvertent reconfiguration of the FPGA, assuming power has been maintained on the standby portion of the FPGA. Further, the control and FPGA module 104 is coupled to an IR detector 180 adapted to receive incoming IR signals, such as those emitted by the remote control 14 (FIG. 1). Upon detecting the IR signals, the IR detector 180 converts the IR signals into electrical signals for processing by the STBY FPGA 160 and the RUN FPGA 162 accordingly.

When the electronic device 100 is in STBY mode, i.e., turned off, only the FPGA 160 may be powered. Specifically, in such a mode the STBY power supply 108 provides low, but sufficient power to the FPGA 160 such that the overall power consumed by the electronic device 100 conforms to industry standards on power consumption. For example, when a user turns the electronic device 100 on, received IR signals corresponding to such an operation are processed by the FPGA 160. As a result, the FPGA 160 provides an output activating the transistor 176, thereby closing the relay switch 118. Consequently, the RUN power supply 110 is enabled such that the control and FPGA module 104 becomes fully operational and available for executing desired RUN mode functionalities.

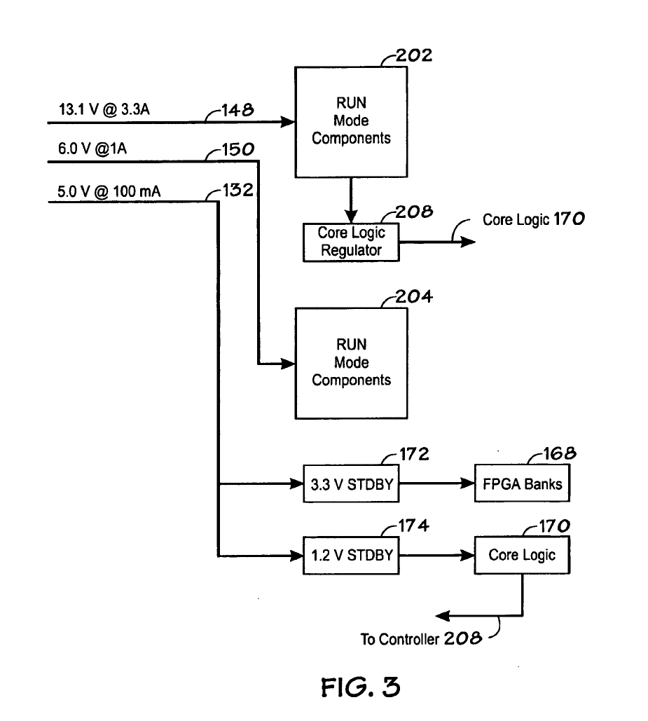

FIG. 3 is a block diagram illustrating allocation of voltages and/or currents to components of the control and FPGA shown in FIG. 2, in accordance with an exemplary embodiment of the present invention. Particularly, FIG. 3 depicts exemplary voltages and currents allocated to components operating while the electronic device is in RUN mode, as well as, to components operating while the electronic device is in STBY mode. Accordingly, the connection lines 148 and 150 are adapted to deliver power to RUN mode devices 202 and 204, respectively. In the illustrated embodiment, connection line 148 may provide RUN mode components 202 with, for example, 13 volts at 3.3 amps, so that those devices may become operational. Such devices may include memory devices, USB drivers, audio buffers and amplifiers, etc. Similarly, RUN mode components 204, which may include tuners, headphones, video cards and so forth, may become operational when provided with 6 volts at 1 amp via the connection line 150.

Further, FIG. 3 illustrates connection line 132 as allocating voltages and/or currents to those components of the electronic device operating in STBY mode. Particularly, voltage regulators 172 and 174 are powered to control FPGA logic banks 168 and core logic 170, respectively. In the illustrated embodiment, connection line 132 may generally deliver STBY voltage of approximately 5 volts at 100 milliamps. For example, such voltage can be allocated between the aforementioned voltage regulators in manner enabling the voltage regulators 172 and 174 to operate at STBY voltages of 3.3 and 1.2 volts, respectively. Such allocation enables the electronic device to operate in STBY mode while consuming energy at a rate in accordance with certain industry standards, such as Energy Star and/or the California energy standard.

Further, as the electronic device transitions from STBY mode the core logic 170 may require an operating current greater than what it normally receives while operating in STBY mode. That is, the STBY current, i.e., 100 milliamps, may be insufficient for that device to properly function as the electronic device 100 transitions from STBY to RUN mode. In order to boost the current, the core logic 170 may be coupled to voltage regulator 208 adapted to increase the current provided to the core logic 170 as the electronic device transitions to RUN mode.

As will be appreciated, the allocation scheme of voltages and/or currents, as described above, is exemplary. Therefore, it should be noted is that other power allocation schemes may be envisioned in accordance with the present technique allowing the electronic device 100 to operate in a manner that complies with the above-mentioned power consumption standards.

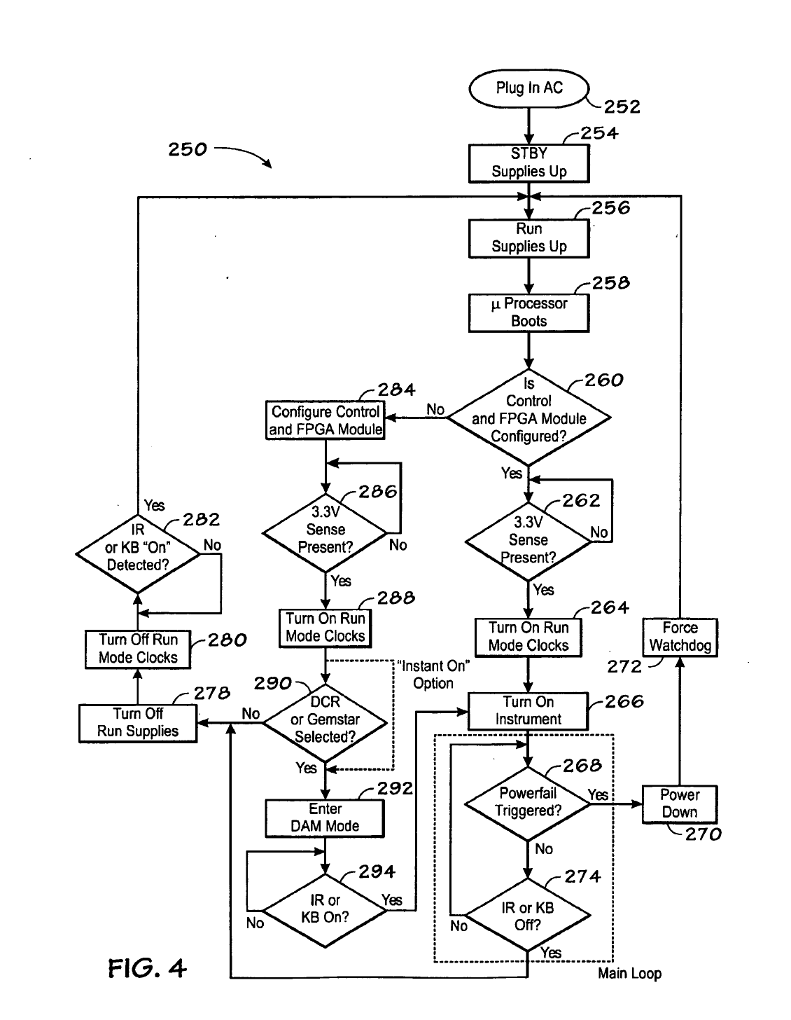

FIG. 4 is a flow chart of a method of operating an electronic device, such as the electronic device 100 (FIG. 2), in accordance with an exemplary embodiment of the present invention. The method begins at block 252 whereby AC voltage is provided to the electronic device. In other words, the method begins when the electronic device is first plugged into a voltage source. Thereafter, the method proceeds to block 254 during which STBY voltage provided to the STBY components of the electronic device is brought up to a desired level. As discussed above, in the illustrated embodiment, such a voltage may be set to 5 volts so as to power the FPGA logic banks 168 and the core logic 170 of the standby mode FPGA 160 discussed in FIG. 2. From block 254, the method proceeds to block 256 during which RUN mode components/devices, such as the transformer 136 and run mode components (e.g., RUN mode components 166) of the FPGA and control module are enabled. It should be appreciated that while at this stage the RUN mode components may become enabled, the light engine (e.g., 106, FIG. 2) of the electronic device remains disabled.

Thereafter, the method proceeds to block 258 whereby the microprocessor such as the controller/microprocessor 164 of the control and FPGA module is powered. During this step, standard boot operation of the microprocessor may take place which may include, for example, memory and driver configurations, system checks, system diagnostics and so forth. From block 258, the method next proceeds to decision junction 260 to determine whether the control and FPGA module (e.g., 104, FIG. 2) is configured. Particularly, at junction 260 it is determined whether the FPGA 160 is configured to handle logic operations associated with STBY mode operations, such as decoding IR signals. If the FPGA 160 is indeed configured, the method then proceeds to decision junction 262. Decision junction 262 is effectively a wait loop, that is, the method 250 does not proceed until the voltage of the voltage regulator adapted to power the FPGA logic banks reaches a desired level. When that occurs, the method proceeds to block 264 whereby RUN mode clocks of the electronic device, particularly those associated with the control and FPGA module, are activated.

Next, the method proceeds from block 264 to block 266 whereby the electronic device is turned on. From block 266, the method proceeds to decision junction 268 to determine whether a power fail should be triggered, that is, whether an event has occurred potentially depriving power from the electronic device during its operation. If such an event occurs, the method proceeds to block 270 whereby the device is powered down. From block 270, the method proceeds to block 272 whereby the device, particularly, the microprocessor associated with the control and FPGA module is reset and/or rebooted. Thereafter, the method returns to the standby mode achieved right after block 254.

Returning to decision junction 268, if a power fail is not triggered, the method proceeds from decision junction 268 to decision junction 274 to determine whether an IR or a keyboard (KB) function is detected turning the electronic device off. If no such signal is detected, the method loops back to decision junction 268. However, if an IR or KB signal is detected, the method proceeds to block 278 whereby RUN mode components and power supply associated therewith are turned off. Next, the method proceeds to block 280 whereby run mode clocks are turned off. Thereafter, the method proceeds to decision junction 282 until an IR or KB signal is detected turning the electronic device on. Once the electronic device is turned on, the method loops back to block 256.

Next, consider the decision junction 260 in the case in which it is determined that the STBY FPGA (e.g., FPGA 160) is not configured. In such a case, the method proceeds to block 284 during which the STBY FPGA undergoes configuration and/or initialization. This may involve transfer of data to the STBY FPGA from non-volatile memory components, such as flash memory, contained within the control and FPGA module (e.g., control and FPGA module 104, FIG. 1). After completion of the configuration of the STBY FPGA, the method proceeds to decision junction 286, which is a wait loop enabling the voltage regulator of the FPGA logic bank to reach a desired level. Once that occurs, the method proceeds to block 288 whereby RUN mode clocks of the electronic device are turned on. Thereafter, the method proceeds to decision junction 290 to determine whether data acquisition mode, such as digital cable ready (DCR) or Gemstar, is selected. Those skilled in the art will appreciate that determining whether a data acquisition mode is selected may determine whether the microprocessor of the control and FPGA module should remain on. If a data acquisition mode is selected, the method proceeds from decision junction 290 to the block 292, whereby a data acquisition mode is entered.

Next, the method proceeds to decision junction 294 to determine whether an IR or a KB signal is detected turning the electronic device on. If such a signal is detected, the method proceeds to block 266 whereby the device is turned on. Returning to decision junction 290, if data acquisition mode is not selected, the method proceeds from decision junction 290 to block 278 whereby RUN mode components of the electronic device are shut down. From block 278, the method 250 ultimately proceeds to the decision junction 282 until an IR or KB signal is detected. If so, the method terminates at block 256.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. An electronic device, comprising:
a logic circuit comprising a plurality of banks, wherein at least one of the plurality of banks is configured to provide standby functionality to the electronic device; and
a power supply coupled to the logic circuit and configured to power the at least one bank without powering all of the plurality of banks.

2. The electronic device of claim 1, wherein the electronic device comprises a television (TV), a digital versatile video recorders (DVDR), a computer, a video cassette recorders (VCR), a video camera, a personal digital assistant (PDA), or a cell phone.

3. The electronic device of claim 1, wherein the logic circuit comprises at least one field programmable gate array (FPGA).

4. The electronic device of claim 1, comprising a microprocessor coupled to the logic circuit and to the power supply.

5. The electronic device of claim 4, wherein the power supply comprises two power submodules, wherein a first submodule is configured to power the logic circuit when the electronic device is in a standby mode, and wherein a second submodule is configured power the plurality of logic circuits when the electronic device is in a run mode.

6. The electronic device of claim 5, comprising a switch, such as a relay, transistor, adapted to connect the two power submodules when the electronic device is in the run mode.

7. The electronic device of claim 1, wherein the electronic device is compliant with an “Energy Star” industry standard, or by a standard dictated by the State of California requiring less than three Watts consumption, or a combination thereof.

8. The electronic device of claim 1, comprising a plurality of voltage regulators adapted to power the plurality of banks.

9. The electronic device of claim 1, wherein the at least one bank is configured to decode infra red (IR) signals by either fully decoding the local keyboard and IR commands or decoding a subset of the keyboard, while the electronic device is in standby mode.

10. The electronic device of claim 1, wherein the plurality of banks are configured to decode infra red (IR) signals while the electronic device is in run mode.

11. A method for operating an electronic device, comprising:
powering at least one of a plurality of banks of a logic circuit adapted to provide standby functionality to the electronic device;
configuring the at least one bank to provide the standby functionality to the electronic device; and
operating the electronic device in a standby mode.

12. The method of claim 11, comprising powering the electronic device in standby mode in accordance with an “Energy Star” industry standard or by a standard dictated by the State of California requiring less than three Watts consumption, or a combination thereof.

13. The method of claim 11, comprising powering portions of run mode components of the electronic device if the logic circuit is configured after the logic circuit is powered.

14. The method of claim 11, comprising decoding infra red signals while the electronic device is in standby mode.

15. The method of claim 11, comprising selecting a data acquisition mode after the logic circuit is configured.

16. An electronic device, comprising:
a computer processing unit;
a logic circuit comprising a plurality of banks, wherein at least one of the plurality of banks is configured to provide standby functionality to the electronic device; and
a power supply coupled to the logic circuit and configured to power the at least one bank without powering all of the plurality of banks and/or the computer processing unit.

17. The electronic device of claim 16, comprising a display system, a sound system, a control system, a power supply, a photo detector, or a combination thereof.

18. The electronic device of claim 16, wherein the logic circuit comprises at least one field programmable gate array (FPGA).

19. The electronic device of claim 16, wherein the power supply comprises two power submodules, wherein a first submodule is configured to power the logic circuit when the electronic device is in a standby mode, and wherein a second submodule is configured power the plurality of logic circuits when the electronic device is in a run mode.

20. The electronic device of claim 16, wherein the electronic device is compliant with an “Energy Star” industry standard or by a standard dictated by the State of California requiring less than three Watts consumption, or a combination thereof.
